(19) United States
(12) Patent Application Publication
(10) Pub. No.: US 2026/0002973 A1
(43) Pub. Date: Jan. 1, 2026

(54) DEVICE OF EVALUATING SEPARATOR SAFETY AND METHOD OF EVALUATING THE SAME

(71) Applicant: Samsung SDI Co., Ltd., Yongin-si (KR)

(72) Inventors: Soyoung PARK, Yongin-si (KR); Sunghoon HA, Yongin-si (KR)

(21) Appl. No.: 18/986,422

(22) Filed: Dec. 18, 2024

(30) Foreign Application Priority Data
Jun. 27, 2024 (KR) 10-2024-0084867

(51) Int. Cl. G01R 31/12; G01R 31/20

(52) U.S. Cl. CPC G01R 31/1263; G01R 31/20

(57) ABSTRACT

A device for evaluating the safety of a separator, including: a pressing unit to apply a pressure to a test sample including a first electrode, a standardized foreign matter, a separator, and a second electrode; an insulation breakdown measurement unit to apply a voltage to the first electrode and the second electrode to measure a breakdown voltage; and a controller to control the pressing unit and the insulation breakdown measurement unit, and determine the safety of the separator based on the measured breakdown voltage. In the test sample, the first electrode, the standardized foreign matter, the separator, and the second electrode are sequentially stacked, and the standardized foreign matter is located between the first electrode and the separator.

### CROSS-REFERENCE TO RELATED APPLICATION

The present application claims priority to and the benefit of Korean Patent Application No. 10-2024-0084687, filed on Jun. 27, 2024, in the Korean Intellectual Property Office, the entire disclosure of which is incorporated by reference herein.

### BACKGROUND

### 1. Field

Aspects of embodiments of the present disclosure relate to a device and a method for evaluating the safety of a separator.

### 2. Description of the Related Art

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly. The large-capacity secondary batteries may be used to verify their safety evaluation.

The above information disclosed in this Background section is for enhancement of understanding of the background of the present disclosure, and therefore, it may contain information that does not constitute related (or prior) art.

### SUMMARY

Among some key items of the safety evaluation, an internal short circuit that may be caused by a foreign matter is particularly critical. When a metallic foreign matter enters an electrode plate, the insulation of a separator may be destroyed, and positive and negative electrodes may come into contact with each other, thereby causing an internal short circuit (ISC) and the formation of a short circuit path. If a short circuit current flows through the short circuit path, Joule heat may be generated, potentially leading to the expansion of an insulation breakdown area. As the amount of current increases, a temperature may rise rapidly. In this case the high temperature may cause the electrolyte to react, which may lead to an ignition.

Embodiments of the present disclosure may be directed to a device and a method capable of evaluating the safety of a separator by standardizing a shape and a size of foreign matter.

These and other aspects and features of the present disclosure will be described in or will be apparent from the following description of embodiments of the present disclosure.

According to one or more embodiments of the present disclosure, a device for evaluating the safety of a separator, includes: a pressing unit configured to apply a pressure to a test sample including a first electrode, a standardized foreign matter, a separator, and a second electrode; an insulation breakdown measurement unit configured to apply a voltage to the first electrode and the second electrode to measure a breakdown voltage; and a controller configured to control the pressing unit and the insulation breakdown measurement unit, and determine the safety of the separator based on the measured breakdown voltage. In the test sample, the first electrode, the standardized foreign matter, the separator, and the second electrode are sequentially stacked, and the standardized foreign matter is located between the first electrode and the separator.

In an embodiment, the standardized foreign matter may be one from among a plurality of standardized foreign matters having spherical shapes with different diameters from each other.

In an embodiment, the standardized foreign matter may be one from among a plurality of standardized foreign matters having cuboids shapes with different heights from each other.

In an embodiment, the standardized foreign matter may be located in a central region of the separator.

In an embodiment, the first electrode may include a material that may be more brittle than that of the second electrode.

In an embodiment, the test sample may further include an electrode assembly that is stacked on at least one of the first electrode or the second electrode, the electrode assembly including a plurality of first electrodes, a plurality of separators, and a plurality of second electrodes.

In an embodiment, the pressure may have a pressure value in a range from an initial applied pressure value to a maximum applied pressure value.

In an embodiment, the initial applied pressure value may correspond to an internal pressure value of an electrode assembly in a beginning-of-life (BOL) state of a secondary battery.

In an embodiment, the maximum applied pressure value may correspond to an internal pressure value of an electrode assembly in an end-of-life (EOL) state of a secondary battery.

In an embodiment, the controller may be configured to control the pressing unit to apply the pressure to the test sample, and subsequently control the insulation breakdown measuring unit after the pressure is applied.

In an embodiment, the controller may be configured to determine that a performance of the separator is satisfactory in response to the measured breakdown voltage being greater than or equal to a reference breakdown voltage.

According to one or more embodiments of the present disclosure, a method for evaluating the safety of a separator, includes: fabricating a test sample including a first electrode, a separator, and a second electrode that are sequentially stacked, and a standardized foreign matter between the first electrode and the separator; applying a pressure to the test sample after placing the test sample in a pressing unit; applying a voltage to the first electrode and the second electrode to measure a breakdown voltage; and determining the safety of the separator based on the measured breakdown voltage.

In an embodiment, the standardized foreign matter may be one from among a plurality of standardized foreign matters having spherical shapes with different diameters from each other, and the fabricating of the test sample may include using one of the plurality of standardized foreign matters as the standardized foreign matter.

In an embodiment, the standardized foreign matter may be one from among a plurality of standardized foreign matters having cuboids shapes with different heights from each other, and the fabricating of the test sample may include using one of the plurality of standardized foreign matters as the standardized foreign matter.

In an embodiment, the fabricating of the test sample may include placing the standardized foreign matter in a central region of the separator.

In an embodiment, the fabricating of the test sample may include stacking an electrode assembly including a plurality of first electrodes, a plurality of separators, and a plurality of second electrodes on at least one of the first electrode or the second electrode.

In an embodiment, the applying of the pressure to the test sample may include setting the pressure to a pressure value in a range from an initial applied pressure value to a maximum applied pressure value.

In an embodiment, the initial applied pressure value may correspond to an internal pressure value of an electrode assembly in a beginning-of-life (BOL) state of a secondary battery.

In an embodiment, the maximum applied pressure value may correspond to an internal pressure value of an electrode assembly in an end-of-life (EOL) state of a secondary battery.

In an embodiment, the determining of the safety of the separator may include determining that a performance of the separator is satisfactory in response to the measured breakdown voltage being greater than or equal to a reference breakdown voltage.

According to some embodiments of the present disclosure, the safety of the separator may be evaluated by using standardized foreign matter that may be obtained by standardizing the shape and the size of the foreign matter, thereby improving a reliability of the evaluation results.

However, the aspects and features of the present disclosure are not limited to those described above, and other aspects and features not mentioned will be clearly understood by a person skilled in the art from the detailed description, described below.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 illustrates an example of a device for evaluating the safety of a separator according to an embodiment of the present disclosure.

FIG. 2 illustrates an example of an electrode assembly that is stacked on each of opposite surfaces of a test sample according to an embodiment of the present disclosure.

FIG. 3 illustrates an example of an electrode assembly that is stacked on one surface of a test sample according to an embodiment of the present disclosure.

FIG. 4 is a flowchart illustrating an example of a method for evaluating the safety of a separator according to an embodiment of the present disclosure.

FIG. 5 illustrates a graph showing a breakdown voltage in relation to a size of a spherical standardized foreign matter according to an embodiment of the present disclosure.

FIG. 6 illustrates a graph showing a breakdown voltage in relation to a size of a spherical standardized foreign matter according to an embodiment of the present disclosure.

FIG. 7 illustrates a graph showing a breakdown voltage in relation to a size of a cuboid-shaped standardized foreign matter according to an embodiment of the present disclosure.

FIG. 8 illustrates a graph showing a breakdown voltage in relation to a size of a cuboid-shaped standardized foreign matter according to an embodiment of the present disclosure.

FIG. 9 illustrates a graph showing a breakdown voltage in relation to an applied load according to an embodiment of the present disclosure.

FIG. 10 illustrates a graph showing a breakdown voltage in relation to an applied load according to an embodiment of the present disclosure.

FIG. 11 illustrates a graph showing a breakdown voltage in relation to an applied load according to an embodiment of the present disclosure.

FIGS. 12-15 illustrate graphs showing breakdown voltages for different kinds of test samples as determined by a separator safety evaluation method according to an embodiment of the present disclosure.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

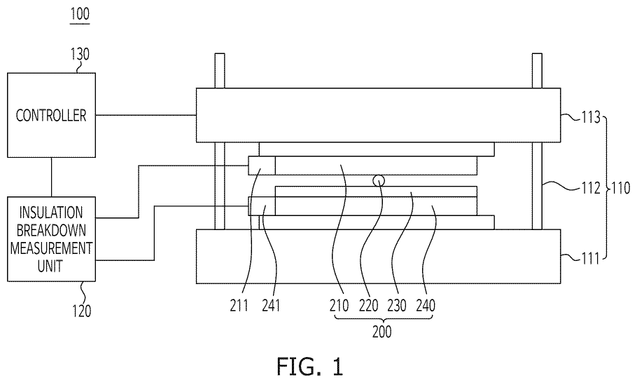

FIG. 1 illustrates an example of a device for evaluating the safety of a separator according to an embodiment of the present disclosure. Referring to FIG. 1, a device 100 for evaluating the safety of a separator (hereinafter, also referred to as “a separator safety evaluation device”) according to an embodiment of the present disclosure may include a pressing unit (e.g., a press) 110 arranged to apply a pressure (e.g., a set or predetermined pressure) to a test sample 200, an insulation breakdown measurement unit (e.g., an insulation breakdown measurer or an insulating breakdown measuring circuit) 120 arranged to measure a breakdown voltage (BDV) by applying a voltage to a first electrode 210 and a second electrode 240 of the test sample 200, and a controller 130 arranged to control the pressing unit 110 and the insulation breakdown measurement unit 120, and determine the safety of a separator 230 based on the measured breakdown voltage.

The test sample 200 may include the first electrode 210, a standardized foreign matter 220, the separator 230, and the second electrode 240. In an embodiment, the test sample 200 may be configured by sequentially stacking the first electrode 210, the standardized foreign matter 220, the separator 230, and the second electrode 240 on one another. The standardized foreign matter 220 may be provided between the first electrode 210 and the separator 230.

In an embodiment, the standardized foreign matter 220 may be one of a plurality of suitable standardized foreign matters formed in spherical shapes having different diameters from each other. For example, the spherical standardized foreign matters may be formed to have various suitable sizes, with diameters ranging from 250 to 750 μm.

In an embodiment, the standardized foreign matter 220 may be one of a plurality of suitable standardized foreign matters formed in cuboids shapes having different heights from each other. The cuboid-shaped standardized foreign matters may be formed to have the same or substantially the same length and width as each other, while the heights thereof may be different from each other. For example, the cuboid-shaped standardized foreign matters may have a length and a width of 300 μm, with a height ranging from 50 to 300 μm. Accordingly, standardized foreign matters having various heights may be formed.

During the manufacturing of an electrode assembly, a possibility of the separator breaking may be relatively low in a case where the actual foreign matter that enters between the electrodes is spherical in shape. However, the possibility of the separator breaking may be relatively high in a case where the actual foreign matter that enters between the electrodes is cuboid in shape. Therefore, even though the actual foreign matter may have an unspecified shape, it may still fall within the shape and size range of the standardized foreign matter. Accordingly, an evaluation result derived using the standardized foreign matter may be applied to foreign matter of any shape, thereby enhancing the reliability of the safety evaluation of the separator conducted with the standardized foreign matter.

The test sample 200 may be fabricated so that the standardized foreign matter 220 is placed in a central region of the separator 230. The central region of the separator 230 may be a region where the greatest pressure is applied. Therefore, in order to evaluate the safety of the separator 230, the safety evaluation may be performed in a state in which the standardized foreign matter 220 is placed in the central region of the separator 230 where the greatest pressure may be applied.

The first electrode 210 may include (e.g., may be made of) a suitable material that is relatively more brittle compared to that of the second electrode 240. A material with a high brittleness may be more easily broken when a pressure is applied. Therefore, in order to evaluate the safety of the separator 230, the safety evaluation may be performed in a state in which the standardized foreign matter 220 is placed between the first electrode 210 including (e.g., made of) a suitable material having a high brittleness and the separator 230.

The first electrode 210 may be formed by applying a first electrode active material, such as a transition metal oxide, on a first electrode current collector formed of a metal foil, such as aluminum or an aluminum alloy. The first electrode 210 may include a first electrode tab 211 (e.g., a first uncoated portion) that is a region to which the first electrode active material is not applied. The first electrode tab 211 may act as a current flow path between the first electrode 210 and the first current collector. In some embodiments, the first electrode tab 211 may be formed by being cut in advance to protrude to the other side (e.g., the opposite side) of the electrode assembly when the first electrode 210 is manufactured, or the first electrode 210 may protrude to the other side of the electrode assembly more than (e.g., farther than or beyond) the separator 230 without being separately cut.

The second electrode 240 may be formed by applying a second electrode active material, such as graphite or carbon, to a second electrode current collector formed of a metal foil, such as copper, a copper alloy, nickel, or a nickel alloy. The second electrode 240 may include a second electrode tab 241 (e.g., a second uncoated portion) that is a region to which the second electrode active material is not applied. The second electrode tab 241 may act as a current flow path between the second electrode 240 and the second current collector. In some embodiments, when the second electrode 240 is manufactured, the second electrode tab 241 may be formed by being cut in advance to protrude to one side of the electrode assembly, or the second electrode tab 241 may protrude to one side of the electrode assembly more than (e.g., farther than or beyond) the separator 230 without being separately cut.

As another example, the first electrode 210 may include an electrode current collector formed of a metal foil, such as copper, a copper alloy, nickel, or a nickel alloy. In this case, the second electrode 240 may include an electrode current collector formed of a metal foil, such as aluminum or an aluminum alloy.

The separator 230 prevents a short circuit between the first electrode 210 and the second electrode 240 while allowing movement of lithium ions therebetween. The separator 230 may be made of, for example, a polyethylene film, a polypropylene film, a polyethylene-polypropylene film, or the like.

The pressing unit 110 may be a device that applies the pressure (e.g., the set or predetermined pressure) to the test sample 200. In an embodiment, the pressing unit 110 may include a lower mold 111, guide bars 112 installed on the lower mold 111, and an upper mold 113 arranged to face the lower mold 111. The upper mold 113 may be vertically movable along the guide bars 112. The upper mold 113 may be equipped with a driving unit (e.g., a driver, a motor, or the like) to move the upper mold 113 in the vertical direction.

The insulation breakdown measurement unit 120 may be connected to the first electrode 210 and the second electrode 240 of the test sample 200. The insulation breakdown measurement unit 120 may apply a voltage to the first electrode 210 and the second electrode 240 to measure a breakdown voltage. In an embodiment, the insulation breakdown measurement unit 120 may apply the voltage linearly for a period of time (e.g., a set or predetermined period of time) to measure the breakdown voltage. For example, the insulation breakdown measurement unit 120 may apply the voltage that linearly increases up to 2 kV for 40 seconds.

When the insulation breakdown measurement unit 120 applies the voltage to the test sample 200 that is being pressed under the pressure, a leakage current may be measured above a voltage (e.g., a certain or predetermined voltage). A value of the leakage current for determining the breakdown voltage may be determined (e.g., may be set) in advance by the insulation breakdown measurement unit 120. The insulation breakdown measurement unit 120 may derive the maximum value from among the voltages at which the value of the leakage current is measured as the breakdown voltage. However, the present disclosure is not limited thereto, and any suitable device and any suitable method as understood by those having ordinary skill in the art may be used.

The controller 130 may control the pressing unit 110 to apply the pressure to the test sample 200. In more detail, the controller 130 may control the pressing unit 110 to ensure that the pressure applied to the test sample 200 remains constant or substantially constant, while a voltage is being applied to the test sample 200.

The pressure may be one of the pressure values in the range from an initial applied pressure value to a maximum applied pressure value.

In an embodiment, the initial applied pressure value may correspond to an internal pressure value of the electrode assembly in the beginning-of-life (BOL) state of the secondary battery. As such, the pressure value may simulate the pressure experienced during an initial charging process of a secondary battery that includes an electrode assembly into which a foreign matter is introduced.

In an embodiment, the maximum applied pressure value may correspond to an internal pressure value of the electrode assembly in the end-of-life (EOL) state of the secondary battery. As such, the pressure value may simulate the pressure experienced in a state in which the electrode assembly into which the foreign matter is introduced has been used up to the EOL state.

As the secondary battery undergoes repeated charging and discharging cycles, the thickness of the cell may increase, which may increase the pressure applied to the electrode assembly. Therefore, the initial applied pressure value, which corresponds to the internal pressure of the electrode assembly in the BOL state of the secondary battery, may serve as a minimum pressure applied to the test sample 200. Further, the maximum applied pressure value, which corresponds to the internal pressure of the electrode assembly in the EOL state of the secondary battery, may serve as the maximum pressure applied to the test sample 200.

The controller 130 may control the insulation breakdown measurement unit 120 to perform its operation after pressing the test sample 200 at the pressure. Then, the controller 130 may receive the breakdown voltage measured by the insulation breakdown measurement unit 120, and may determine that the performance of the separator 230 is satisfactory in response to a case where the measured breakdown voltage is greater than or equal to a reference breakdown voltage (e.g., a predetermined reference breakdown voltage). For example, in a case where the controller 130 determines or sets the reference breakdown voltage to 500 V, it may be determine that the performance of the separator 230 is satisfactory in response to a case where the measured breakdown voltage is 500 V or greater.

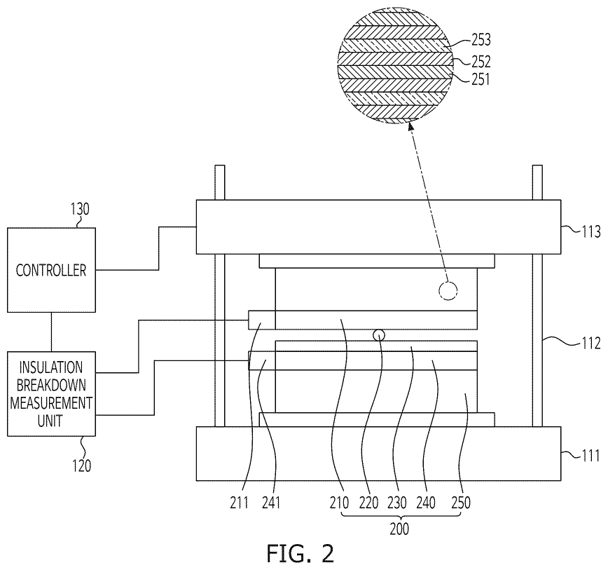

In some embodiments, the test sample 200 may further include an electrode assembly 250 (e.g., see FIG. 2), which is stacked on at least one of the first electrode 210 or the second electrode 240. The electrode assembly 250 may include a plurality of first electrodes 251, a plurality of separators 252, and a plurality of second electrodes 253.

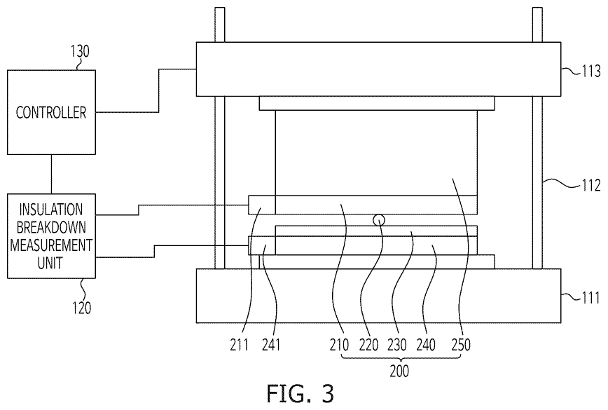

FIG. 2 illustrates an example of an electrode assembly that is stacked on each of opposite surfaces of a test sample according to an embodiment of the present disclosure. FIG. 3 illustrates an example of an electrode assembly that is stacked on one surface of a test sample according to an embodiment of the present disclosure.

Referring to FIG. 2, the test sample 200 may have a structure in which an electrode assembly 250 is further stacked on each of the first electrode 210 and the second electrode 240. The structure may simulate a structure of the form of the electrode assembly used in the actual secondary battery. A thickness of the electrode assembly 250 stacked on the first electrode 210 and a thickness of the electrode assembly 250 stacked on the second electrode 240 may be the same or substantially the same as each other. In other words, the standardized foreign matter 220 may be positioned at the center of the electrode assembly 250. In a case where the standardized foreign matter 220 is positioned at the center of the electrode assembly 250, the greatest pressure may be applied to the standardized foreign matter 220. However, the performance evaluation is not limited to the standardized foreign matter 220 being disposed at (e.g., being disposed only at) the center of the electrode assembly 250. For example, as shown in FIG. 3, the performance evaluation may be carried out in a state in which the standardized foreign matter 220 is disposed at an outermost part of the electrode assembly 250.

Referring to FIG. 3, the test sample 200 may have a structure in which the electrode assembly 250 is stacked on the first electrode 210. The structure may simulate a structure of the form of the electrode assembly used in the actual secondary battery with the standardized foreign matter 220 positioned at the outermost part of the electrode assembly 250. However, the present disclosure is not limited thereto, and the test sample may have a structure in which the electrode assembly is stacked on the second electrode 240.

As such, the standardized foreign matter 220 may be positioned at the center or the outermost part of the electrode assembly 250. As another example, the safety evaluation may also be carried out with the standardized foreign matter 220 disposed between the center and the outermost part of the electrode assembly 250.

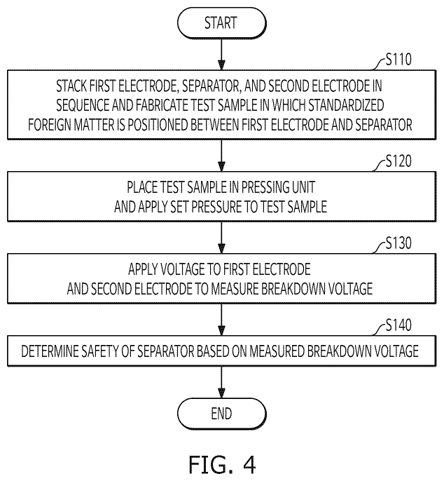

FIG. 4 is a flowchart illustrating an example of a method for evaluating the safety of a separator according to an embodiment of the present disclosure.

Referring to FIG. 4, the method for evaluating the safety of a separator (hereinafter, also referred to as “the separator safety evaluation method”) according to the present embodiment may include stacking a first electrode, a separator, and a second electrode in sequence, and fabricating a test sample in which a standardized foreign matter is positioned between the first electrode and the separator (S110). The method may further include placing the test sample in a pressing unit (e.g., a press), and applying a pressure (e.g., a set or predetermined pressure) to the test sample (S120). The method may further include applying a voltage to the first electrode and the second electrode to measure a breakdown voltage (S130), and determining the safety of the separator based on the measured breakdown voltage (S140).

The fabricating of the test sample (e.g., S110) may include the stacking of the first electrode, the standardized foreign matter, the separator, and the second electrode in sequence to fabricate the test sample. In other words, the standardized foreign matter may be positioned between the first electrode and the separator.

In the fabricating of the test sample (e.g., S110) according to an embodiment, one of a plurality of standardized foreign matters formed in spherical shapes having different diameters from each other may be used to fabricate the test sample. For example, the spherical standardized foreign matters may be formed to have various suitable sizes, with diameters ranging from 250 to 750 μm.

In the fabricating of the test sample (e.g., S110) according to an embodiment, one of a plurality of standardized foreign matters formed in cuboids shapes having different heights from each other may be used to fabricate the test sample. The cuboid-shaped standardized foreign matters may be formed to have the same or substantially the same length and width as each other, while the heights thereof may be different from each other. For example, the cuboid-shaped standardized foreign matters may have a length and a width of 300 μm, with heights ranging from 50 to 300 μm.

The fabricating of the test sample (e.g., S110) according to an embodiment may include placing the standardized foreign matter in a central region of the separator. The central region of the separator may be a region where the greatest pressure is applied. To evaluate the safety of the separator under more severe conditions, the safety evaluation may be performed in a state where the standardized foreign matter is placed in the central region of the separator where the greatest pressure is applied.

The fabricating of the test sample (e.g., S110) according to an embodiment may further include stacking an electrode assembly, which includes a plurality of first electrodes, a plurality of separators, and a plurality of second electrodes, on at least one of the first electrode or the second electrode. In more detail, as shown in FIG. 2, the electrode assembly may be stacked on each of the first electrode and the second electrode, such that the standardized foreign matter is positioned at the center of the electrode assembly. As another example, as shown in FIG. 3, the electrode assembly may be stacked on the first electrode, such that the standardized foreign matter is positioned at the outermost part of the electrode assembly. As another example, the test sample may have a structure in which the electrode assembly is stacked on the second electrode.

Thus, the standardized foreign matter may be positioned at the center or the outermost part of the electrode assembly. As another example, the safety evaluation may also be carried out with the standardized foreign matter disposed between the center and the outermost part of the electrode assembly.

The pressing of the test sample (e.g., S120) may include applying a pressure (e.g., a set or predetermined pressure) to the test sample. In more detail, the pressing of the test sample may include pressing the test sample so that the pressure applied to the test sample remains constant or substantially constant, and does not fluctuate while the voltage is applied to the test sample.

The pressing of the test sample (e.g., S120) according to an embodiment may include setting the pressure to a value in a range from an initial applied pressure value to a maximum applied pressure value.

The initial applied pressure value according to an embodiment may correspond to an internal pressure value of the electrode assembly in the beginning-of-life (BOL) state of the secondary battery. The pressure value may simulate the pressure experienced during an initial charging process of a secondary battery including an electrode assembly into which a foreign matter is introduced.

The maximum applied pressure value according to an embodiment may correspond to an internal pressure value of the electrode assembly in the end-of-life (EOL) state of the secondary battery. The pressure value may simulate the pressure experienced in a state in which the electrode assembly into which the foreign matter is introduced has been used up to the EOL state.

The determining of the safety of the separator (e.g., S140) may include determining that a performance of the separator is satisfactory in response to a case where the measured breakdown voltage is greater than or equal to a reference breakdown voltage (e.g., a predetermined reference breakdown voltage). For example, in the determining of the safety of the separator, in a case where the reference breakdown voltage is 500 V, the performance of the separator may be determined to be satisfactory in response to a case where the measured breakdown voltage is 500 V or greater.

Hereinafter, results obtained using the separator safety evaluation device and the separator safety evaluation method according to some embodiments of the present disclosure will be described in detail.

To evaluate the safety of the separator under more severe conditions, in the test sample prepared for the safety evaluation of the separator, the standardized foreign matter may be positioned in the central region of the separator where the greatest pressure is applied. As shown in FIG. 2, the electrode assembly 250 may be stacked on each of the first and second electrodes, and the standardized foreign matter may be positioned at the center of the electrode assembly 250 to perform the safety evaluation.

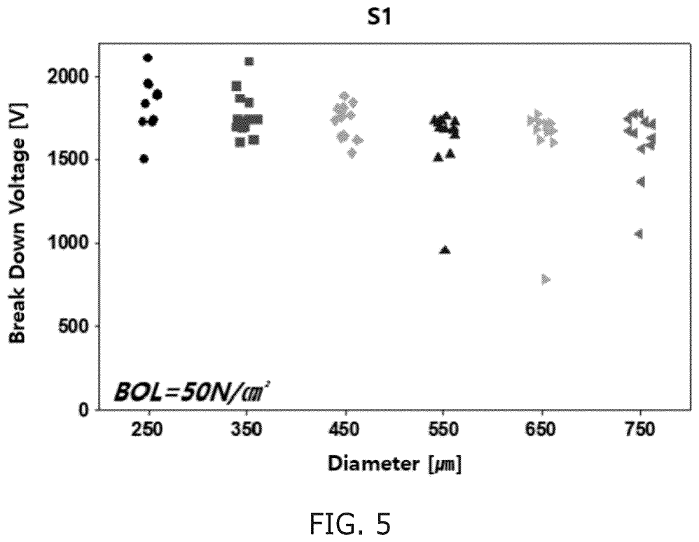

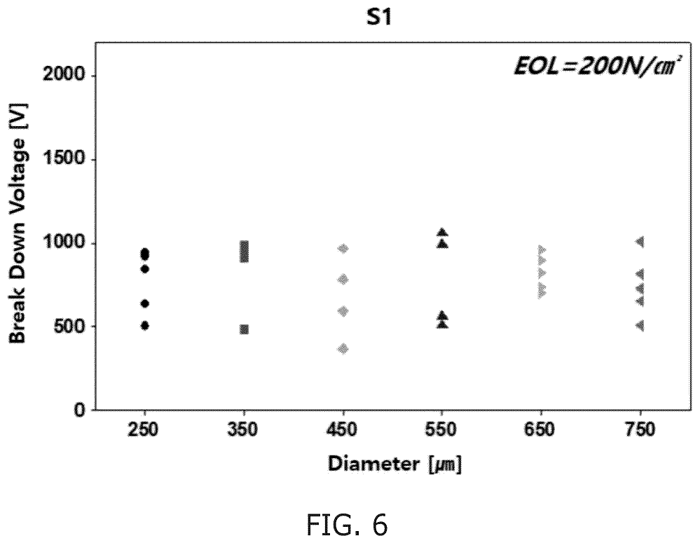

FIG. 5 illustrates a graph showing a breakdown voltage in relation to a size of a spherical standardized foreign matter according to an embodiment of the present disclosure. FIG. 6 illustrates a graph showing a breakdown voltage in relation to a size of a spherical standardized foreign matter according to an embodiment of the present disclosure. FIG. 5 and FIG. 6 illustrate graphs showing breakdown voltages in relation to a size of a spherical standardized foreign matter, which is derived from a separator safety evaluation method according to an embodiment of the present disclosure. In the safety evaluations shown in FIG. 5 and FIG. 6, spherical standardized foreign matters with diameters ranging from 250 to 750 μm are used. A first test sample S1 is fabricated by stacking a ceramic-coated separator having a thickness of 14 μm between the first electrode and the second electrode, and placing the standardized foreign matter between the first electrode and the separator.

FIG. 5 shows a result in a case where a pressure applied to the first test sample S1 is 50 N/cm². The pressure value may be an initial applied pressure value that corresponds to the internal pressure value of the electrode assembly in the BOL state of the secondary battery. However, the initial applied pressure value is not limited thereto, and the initial applied pressure value may be variously modified depending on the size, thickness, and kind of the electrode assembly, as well as the thickness and kind of the separator.

Referring to FIG. 5, in the case of the standardized foreign matter having the diameter ranging from 250 to 450 μm, the insulation breakdown of the first test sample S1 may occur in a range from approximately 1,500 to 2,000 V. Further, in the case of the standardized foreign matter having the diameter ranging from 550 and 750 μm, the insulation breakdown occurs in a range from approximately 900 to 1,800 V.

FIG. 6 shows a result in a case where a pressure applied to the first test sample S1 is 200 N/cm². The pressure value may be a maximum applied pressure value that corresponds to the internal pressure value of the electrode assembly in the EOL state of the secondary battery. However, the maximum applied pressure value is not limited thereto, and the maximum applied pressure value may be variously modified depending on the size, thickness, and kind of the electrode assembly, as well as, the thickness and kind of the separator.

Referring to FIG. 6, in the case of the standardized foreign matter having the diameter ranging from 250 to 750 μm, the insulation breakdown of the first test sample S1 occurs in a range from approximately 400 to 1,000 V.

Comparing the results illustrated in FIG. 5 and FIG. 6, the insulation breakdown occurs more rapidly as the applied pressure increases.

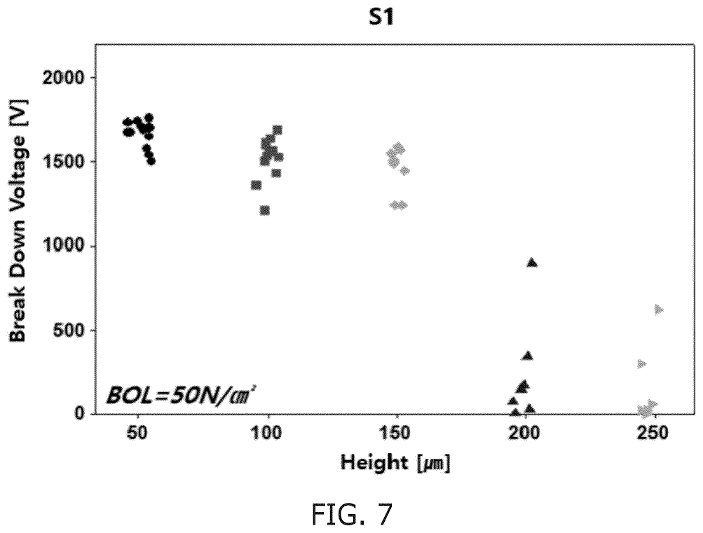

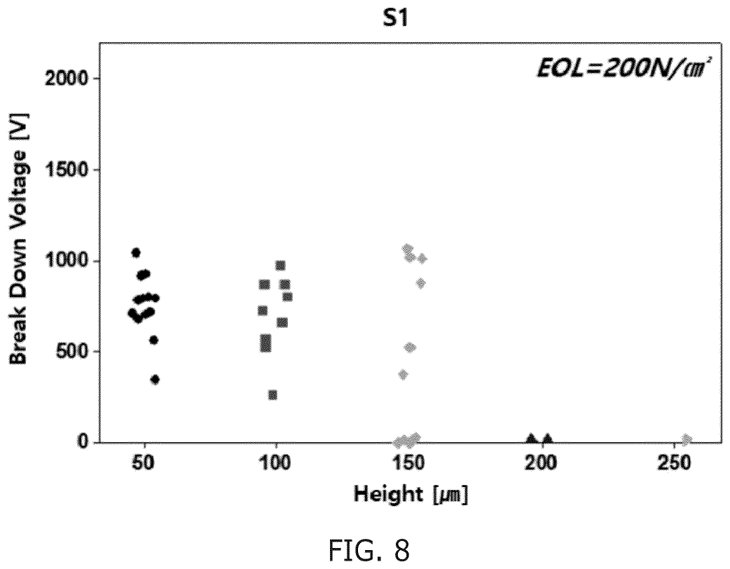

FIG. 7 illustrates a graph showing a breakdown voltage in relation to a size of a cuboid-shaped standardized foreign matter according to an embodiment of the present disclosure. FIG. 8 illustrates a graph showing a breakdown voltage in relation to a size of a cuboid-shaped standardized foreign matter according to an embodiment of the present disclosure. FIG. 7 and FIG. 8 illustrate graphs showing breakdown voltages in relation to a size of a cuboid-shaped standardized foreign matter, which is derived from a separator safety evaluation method according to an embodiment of the present disclosure.

In the safety evaluations shown in FIG. 7 and FIG. 8, cuboid-shaped standardized foreign matters having a length and a width of 300 μm and heights ranging from 50 to 250 μm are used. A first test sample S1 is fabricated by stacking a ceramic-coated separator having a thickness of 14 μm between the first electrode and the second electrode, and placing the standardized foreign matter between the first electrode and the separator.

FIG. 7 shows a result in a case where a pressure applied to the first test sample S1 is 50 N/cm². Referring to FIG. 7, in the case of the standardized foreign matter having the height ranging from 50 and 150 μm, the insulation breakdown of the first test sample S1 occurs in a range from approximately 1,200 to 1,800 V. Further, in the case of the standardized foreign matter having the height ranging from 200 and 250 μm, the insulation breakdown occurs in a range from the beginning of a voltage application to approximately 900 V.

FIG. 8 shows a result in a case where a pressure applied to the first test sample S1 is 200 N/cm². Referring to FIG. 8, in the case of the standardized foreign matter having the height ranging from 50 to 150 μm, the insulation breakdown of the first test sample S1 occurs in a range from approximately 0 to 1,000 V. Further, in the case of the standardized foreign matter having the height ranging from 200 to 250 μm, the insulation breakdown occurs at the beginning of a voltage application.

Comparing the results illustrated in FIG. 7 and FIG. 8, the insulation breakdown occurs more rapidly as the applied pressure increases.

Further, comparing the results illustrated in FIG. 5 with FIG. 7 and FIG. 6 with FIG. 8, in the case of the standardized foreign matter being in a cuboid shape, the insulation breakdown occurs more quickly than in the case of the standardized foreign matter being spherical. As such, when the foreign matter has a more angular shape, like a cuboid shape, insulation breakdown may occur more rapidly.

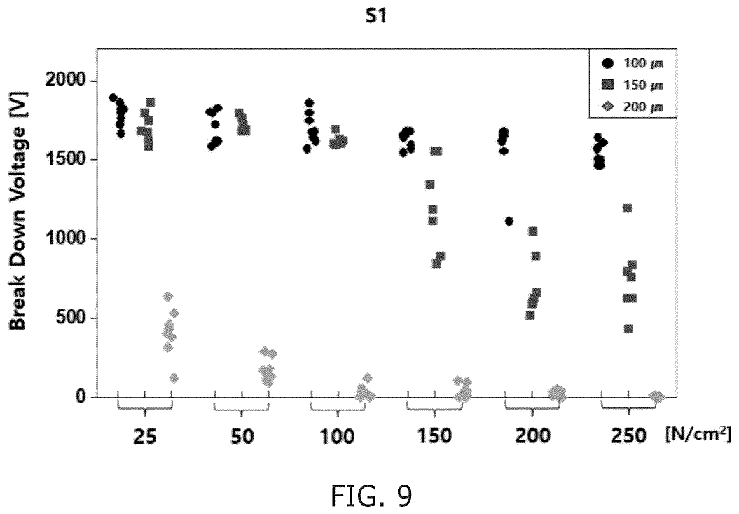

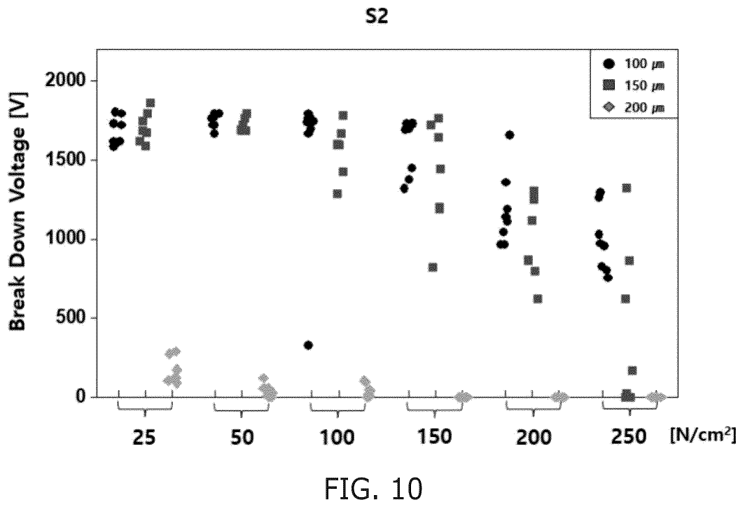

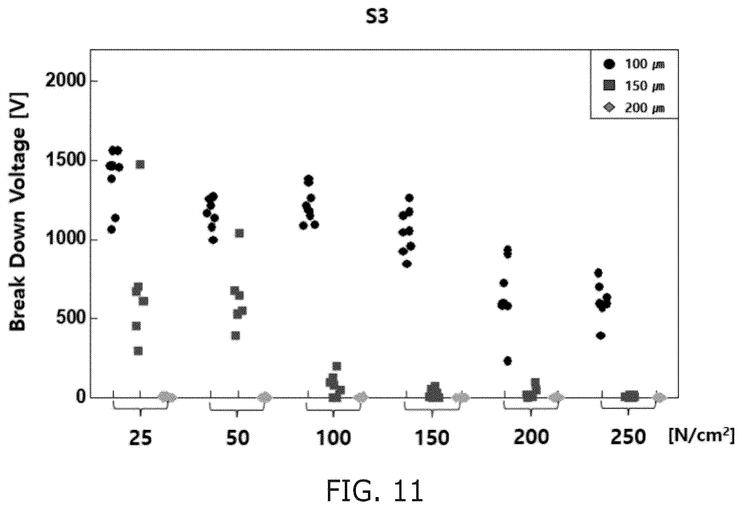

FIG. 9 illustrates a graph showing a breakdown voltage in relation to an applied load according to an embodiment of the present disclosure. FIG. 10 illustrates a graph showing a breakdown voltage in relation to an applied load according to an embodiment of the present disclosure. FIG. 11 illustrates a graph showing a breakdown voltage in relation to an applied load according to an embodiment of the present disclosure. FIGS. 9 to 11 are graphs illustrating breakdown voltages in relation to an applied load, which is derived from a separator safety evaluation method according to an embodiment of the present disclosure. In the safety evaluations shown in FIGS. 9 to 11, cuboid-shaped standardized foreign matters having a length and a width of 300 μm and heights of 100 μm, 150 μm, and 200 μm are used. The applied pressure is ranged from 25 to 250 N/cm².

FIG. 9 illustrates the evaluation performed using a first test sample S1. The first test sample S1 is fabricated by stacking a ceramic-coated separator having a thickness of 14 μm between the first electrode and the second electrode, and placing a standardized foreign matter between the first electrode and the separator.

Referring to FIG. 9, in the case of the standardized foreign matter having the height of 100 μm, an insulation breakdown occurs in a range from approximately 1,500 to 1,900 V at an applied pressure ranging from 25 to 100 N/cm², and the insulation breakdown occurs in a range from approximately 1,500 to 1,700 V at the applied pressure ranging from 150 to 250 N/cm².

Further, referring to FIG. 9, in the case of the standardized foreign matter having the height of 150 μm, the insulation breakdown occurs in the range from approximately 1,500 to 1,900 V at the applied pressure ranging from 25 to 100 N/cm², and the insulation breakdown occurs in a range from approximately 500 to 1,500 V at the applied pressure ranging from 150 to 250 N/cm².

Further, referring to FIG. 9, in the case of the standardized foreign matter having the height of 200 μm, the insulation breakdown occurs in a range from approximately 100 to 600 V at the applied pressure ranging from 25 to 50 N/cm², and the insulation breakdown occurs in the range from the beginning of voltage application to approximately 100V at the applied pressure ranging from 100 to 250 N/cm².

As the applied load increases, the insulation breakdown occurs more rapidly, indicating that the probability of insulation breakdown increases as the usage cycles of the secondary battery increases. Furthermore as the size of the standardized foreign matter increases, the insulation breakdown occurs more quickly. In more detail, in the case of the standardized foreign matter having the height of 200 μm, there may be a higher probability that the insulation breakdown will occur from the beginning of a voltage application.

FIG. 10 illustrates the evaluation performed using a second test sample S2. The second test sample S2 is fabricated by stacking a multi-layered coated separator having a thickness of 13 μm between the first electrode and the second electrode, and placing a standardized foreign matter between the first electrode and the separator. The multi-layered coated separator may be fabricated by applying two or more coating layers, such as alumina and magnesium hydroxide.

Referring to FIG. 10, in the case of the standardized foreign matter having the height of 100 μm, the insulation breakdown occurs in a range from approximately 1,500 to 1,800 V at the applied pressure ranging from 25 to 100 N/cm², and the insulation breakdown occurs in a range from approximately 1,000 to 1,700 V at the applied pressure ranging from 150 to 250 N/cm².

Further, referring to FIG. 10, in the case of the standardized foreign matter having the height of 150 μm, the insulation breakdown occurs in a range from approximately 1,500 to 1,900 V at the applied pressure ranging from 25 to 50 N/cm², the insulation breakdown occurs in a range from approximately 500 to 1,900 V at the applied pressure ranging from 100 and 200 N/cm², and the insulation breakdown occurs in a range from the beginning of a voltage application to approximately 1,300 V at the applied pressure of 250 N/cm².

Further, referring to FIG. 10, in the case of the standardized foreign matter having the height of 200 μm, the insulation breakdown occurs in a range from approximately 100 to 300 V at the applied pressure of 25 N/cm², the insulation breakdown occurs in a range from the beginning of voltage application to approximately 200 V at the applied pressure ranging from 50 to 100 N/cm², and the insulation breakdown occurs at the beginning of a voltage application at the applied pressure ranging from 150 to 250 N/cm².

In comparing between FIG. 9 and FIG. 10, the breakdown voltage varies depending on the kind and the thickness of the separator. Further, regardless of the kind of the separator, the insulation breakdown tends to occur more rapidly as the applied load increases. Furthermore, as the size of the standardized foreign matter increases, the insulation breakdown occurs more rapidly. In more detail, in the case of the standardized foreign matter having the height of 200 μm, there may be a higher probability that the insulation breakdown will occur from the beginning of a voltage application.

FIG. 11 illustrates the evaluation performed using a third test sample S3. The third test sample S3 is fabricated by stacking a multi-layered coated separator having a thickness of 12 μm between the first electrode and the second electrode, and placing a standardized foreign matter between the first electrode and the separator.

Referring to FIG. 11, in the case of the standardized foreign matter having the height of 100 μm, the insulation breakdown occurs in a range from approximately 800 to 1,600 V at the applied pressure ranging from 25 to 150 N/cm², and the insulation breakdown occurs in a range from approximately 300 to 1,000 V at the applied pressure ranging from 200 to 250 N/cm².

Further, referring to FIG. 11, in the case of the standardized foreign matter having the height of 150 μm, the insulation breakdown occurs in a range from approximately 300 to 1,500 V at the applied pressure ranging from 25 to 50 N/cm², the insulation breakdown occurs in a range from the beginning of a voltage application to approximately 200 V at the applied pressure ranging from 100 to 200 N/cm², and the insulation breakdown occurs at the beginning of a voltage application at the applied pressure of 250 N/cm².

Further, referring to FIG. 11, in the case of the standardized foreign matter having the height of 200 μm, the insulation breakdown occurs at the beginning of a voltage application across the entire applied pressure ranging from 25 to 250 N/cm².

In comparing between FIG. 10 and FIG. 11, even when the kind of the separator remains the same, variations in the thickness may result in different breakdown voltages. Furthermore, regardless of the thickness of the separator, the insulation breakdown tends to occur more rapidly as the applied load increases. Furthermore, as the size of the standardized foreign matter increases, the insulation breakdown occurs more rapidly. In more detail, in the case of the standardized foreign matter having the height of 200 μm, there may be a higher probability that the insulation breakdown will occur from the beginning of a voltage application.

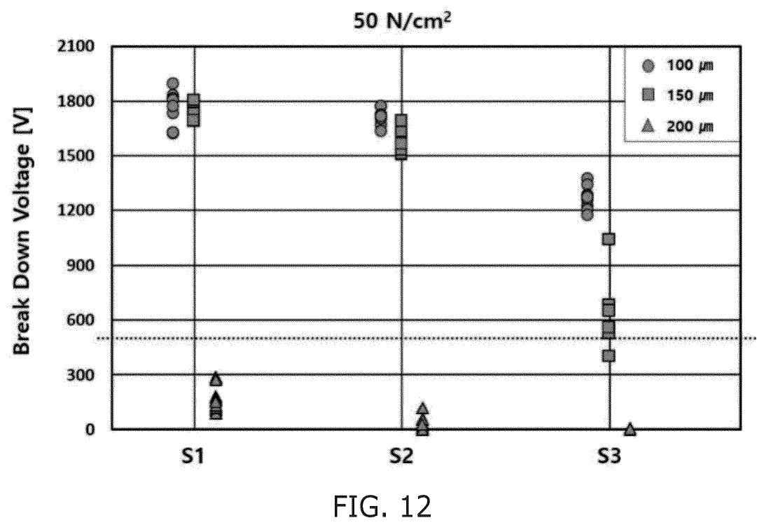

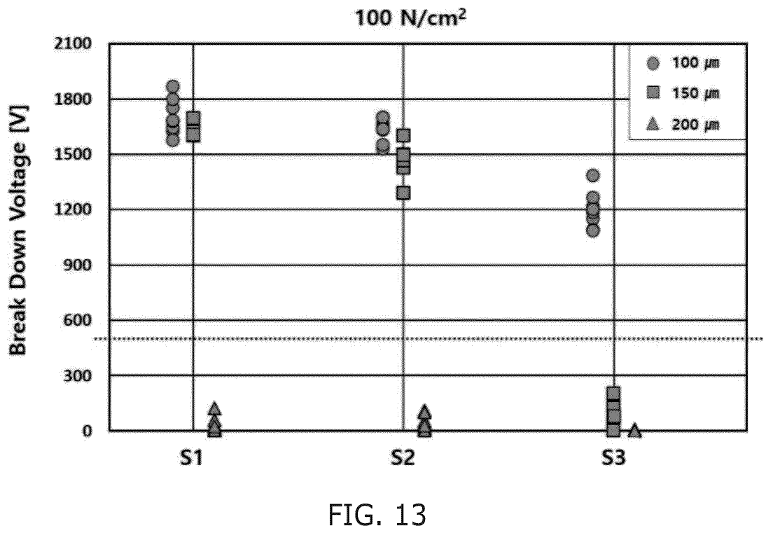

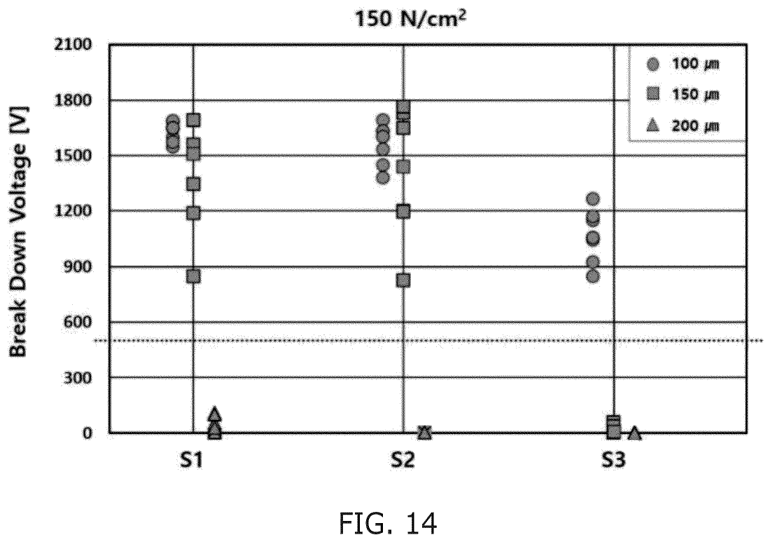

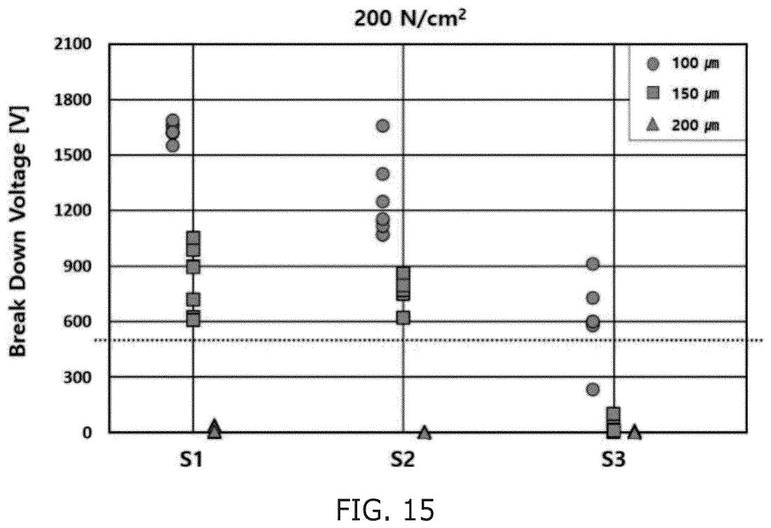

FIGS. 12 through 15 illustrate graphs showing breakdown voltages for different kinds of test samples as determined by a separator safety evaluation method according to an embodiment of the present disclosure. In FIGS. 12 to 15, the breakdown voltages of the first test sample S1, the second test sample S2, and the third test sample S3 are compared based on the applied pressure. Further, cuboid-shaped standardized foreign matters having a length and a width of 300 μm and heights of 100 μm, 150 μm, and 200 μm are used. Further, a reference breakdown voltage for determining that the separators performance is good is set to 500 V, and the safety of the separator of each test sample is evaluated.

Referring to FIGS. 12 to 15, in the case of the standardized foreign matter having the height of 100 μm, the breakdown voltages of all the test samples are 500 V or higher at the applied pressure ranging from 50 to 150 N/cm², indicating that all separators are considered stable. However, at the applied pressure of 200 N/cm², the separators of the first test sample S1 and the second test sample S2 are considered stable, but the breakdown voltages of the third test sample S3 fall below 500 V, indicating that the separator is considered relatively unstable.

As such, in the case of the standardized foreign matter having the height of 100 μm, all of the separators may be used stably. However, the separator of the third test sample S3 shows reduced safety as it approaches the EOL cycle.

Further, referring to FIGS. 12 to 15, in the case of the standardized foreign matter having the height of 150 μm, the breakdown voltages of the first test sample S1 and the second test sample S2 are 500V or higher at the applied pressures ranging from 50 to 200 N/cm², indicating that the separators are considered stable. However, the third test sample S3 shows instability from the beginning with the breakdown voltages ranging from approximately 400 to 700V at the applied pressure of 50 N/cm², and the insulation breakdown occurs from the beginning of a voltage application at the applied pressure ranging from 100 to 200 N/cm², confirming that the separator may be difficult to use under these conditions.

Accordingly, in the case of the standardized foreign matter having the height of 150 μm, the separators of the first test sample S1 and the second test sample S2 may be used stably. However, the third test sample S3 exhibits the breakdown voltages below 500V from the beginning of the BOL cycle, and as the number of cycles increases thereafter, the insulation breakdown occurs from the beginning of voltage application, indicating that the separator is unsuitable for use under these conditions.

Furthermore, referring to FIGS. 12 to 15, in the case of the standardized foreign matter having the height of 200 μm, all test samples exhibit the breakdown voltages below 500V from the beginning of the BOL cycle, and as the number of cycles increases thereafter, the insulation breakdown occurs from the beginning of a voltage application, indicating that the separator is unsuitable for use under these conditions.

As described above, by standardizing the shape and the size of the foreign matter, and measuring the breakdown voltage of the separator under different applied loads using the standardized foreign matter, the safety of the separator may be evaluated in response to the size of the foreign matter and the usage cycles of the secondary battery. Accordingly, an appropriate kind and thickness of the separator may be determined.

The electronic or electric devices and/or any other relevant devices or components according to embodiments of the present disclosure described herein (e.g., the controller, the insulating breakdown measurement unit, and/or the like) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure and the claims and their equivalents, below.

What is claimed is:

1. A device for evaluating the safety of a separator, the device comprising:
a pressing unit configured to apply a pressure to a test sample comprising a first electrode, a standardized foreign matter, a separator, and a second electrode;
an insulation breakdown measurement unit configured to apply a voltage to the first electrode and the second electrode to measure a breakdown voltage; and
a controller configured to control the pressing unit and the insulation breakdown measurement unit, and determine the safety of the separator based on the measured breakdown voltage,
wherein, in the test sample, the first electrode, the standardized foreign matter, the separator, and the second electrode are sequentially stacked, and the standardized foreign matter is located between the first electrode and the separator.

2. The device as claimed in claim 1, wherein the standardized foreign matter is one from among a plurality of standardized foreign matters having spherical shapes with different diameters from each other.

3. The device as claimed in claim 1, wherein the standardized foreign matter is one from among a plurality of standardized foreign matters having cuboids shapes with different heights from each other.

4. The device as claimed in claim 1, wherein the standardized foreign matter is located in a central region of the separator.

5. The device as claimed in claim 1, wherein the first electrode comprises a material that is more brittle than that of the second electrode.

6. The device as claimed in claim 1, wherein the test sample further comprises an electrode assembly that is stacked on at least one of the first electrode or the second electrode, the electrode assembly comprising a plurality of first electrodes, a plurality of separators, and a plurality of second electrodes.

7. The device as claimed in claim 1, wherein the pressure has a pressure value in a range from an initial applied pressure value to a maximum applied pressure value.

8. The device as claimed in claim 7, wherein the initial applied pressure value corresponds to an internal pressure value of an electrode assembly in a beginning-of-life (BOL) state of a secondary battery.

9. The device as claimed in claim 7, wherein the maximum applied pressure value corresponds to an internal pressure value of an electrode assembly in an end-of-life (EOL) state of a secondary battery.

10. The device as claimed in claim 1, wherein the controller is configured to control the pressing unit to apply the pressure to the test sample, and subsequently control the insulation breakdown measuring unit after the pressure is applied.

11. The device as claimed in claim 1, wherein the controller is configured to determine that a performance of the separator is satisfactory in response to the measured breakdown voltage being greater than or equal to a reference breakdown voltage.

12. A method for evaluating the safety of a separator, the method comprising:
fabricating a test sample comprising a first electrode, a separator, and a second electrode that are sequentially stacked, and a standardized foreign matter between the first electrode and the separator;
applying a pressure to the test sample after placing the test sample in a pressing unit;
applying a voltage to the first electrode and the second electrode to measure a breakdown voltage; and
determining the safety of the separator based on the measured breakdown voltage.

13. The method as claimed in claim 12, wherein the standardized foreign matter is one from among a plurality of standardized foreign matters having spherical shapes with different diameters from each other, and
wherein the fabricating of the test sample comprises using one of the plurality of standardized foreign matters as the standardized foreign matter.

14. The method as claimed in claim 12, wherein the standardized foreign matter is one from among a plurality of standardized foreign matters having cuboids shapes with different heights from each other, and
wherein the fabricating of the test sample comprises using one of the plurality of standardized foreign matters as the standardized foreign matter.

15. The method as claimed in claim 12, wherein the fabricating of the test sample comprises placing the standardized foreign matter in a central region of the separator.

16. The method as claimed in claim 12, wherein the fabricating of the test sample comprises stacking an electrode assembly comprising a plurality of first electrodes, a plurality of separators, and a plurality of second electrodes on at least one of the first electrode or the second electrode.

17. The method as claimed in claim 12, wherein the applying of the pressure to the test sample comprises setting the pressure to a pressure value in a range from an initial applied pressure value to a maximum applied pressure value.

18. The method as claimed in claim 17, wherein the initial applied pressure value corresponds to an internal pressure value of an electrode assembly in a beginning-of-life (BOL) state of a secondary battery.

19. The method as claimed in claim 17, wherein the maximum applied pressure value corresponds to an internal pressure value of an electrode assembly in an end-of-life (EOL) state of a secondary battery.

20. The method as claimed in claim 12, wherein the determining of the safety of the separator comprises determining that a performance of the separator is satisfactory in response to the measured breakdown voltage being greater than or equal to a reference breakdown voltage.
